(19) United States
(12) Patent Application Publication
(10) Pub. No.: US 2004/0196936 A1
(43) Pub. Date: Oct. 7, 2004

(54) Switched capacitor filter and digital wireless receiver

(76) Inventors: Shuichi Kawama, Kyoto-shi (JP); Shinichiro Azuma, Ikoma-gun (JP); Kunihiko Iizuka, Sakurai-shi (JP)

Correspondence Address: BIRCH STEWART KOLASCH & BIRCH, PO BOX 747, FALLS CHURCH, VA, 22040-0747, US

(21) Appl. No.: 10/802,838

(22) Filed: Mar. 18, 2004

(30) Foreign Application Priority Data
Apr. 2, 2003 (JP) 2003-098844

(51) Int. Cl. H03M 3/00

(52) U.S. Cl. 375/350

(57) ABSTRACT

A switched capacitor filter having an anti-aliasing function includes integration circuits of multiple-stages, each of which is provided with an amplifier and a switched capacitor. At least an integration circuit of the first stage has a resistor. In the filter, bipolar transistors are used for the input stage of an amplifier in at least one of the integration circuits having a resistor. On the account of this, 1/f noise is reduced.

This Nonprovisional application claims priority under 35 U.S.C. § 119(a) on Patent Application No. 2003/098844 filed in Japan on Apr. 2, 2003, the entire contents of which are hereby incorporated by reference.

### FIELD OF THE INVENTION

The present invention relates to noise reduction in a switched capacitor filter having an anti-aliasing function.

### BACKGROUND OF THE INVENTION

A discrete-time filter using a switched capacitor requires that a sampled analog signal is inputted every unit time. Therefore, a sample/hold (S/H) circuit requires to be provided in front of the switched capacitor filter in order to input an analog signal, which is a normal continuous-time signal, into the switched capacitor filter. The S/H function can be rendered by modifying a structure of the switched capacitor circuit in a first stage of the switched capacitor filter. Also, sampling generates aliasing noise.

The aliasing noise occurs when a frequency component not less than half the sampling frequency enters a frequency half the sampling frequency. In order to remove aliasing noise, a continuous-time low-pass filter, which is used to sufficiently attenuate a frequency component not less than half the sampling frequency, requires to be provided in front of the S/H circuit. The continuous-time filter is called an “anti-aliasing filter.”

The inventors of the present invention have proposed a switched capacitor having an anti-aliasing function, for example, in “Embedded Anti-Aliasing in Switched Capacitor Ladder Filters With Variable Gain and Offset Compensation,” Shin'ichiro Azuma, et al., IEEE Journal of Solid-State Circuit, Institute of Electrical and Electronics Engineers, Volume 3, third issue, pp.349-356 (March 2002). In this filter, some of the switched capacitors in the first and subsequent stages of the switched capacitor filter are replaced with resistors. The replaced stages process both a continuous-time analog signal and a discrete-time analog signal. As a result of this, a high-pass component of the continuous-time analog signal is attenuated to a level that does not cause aliasing, whereas a discrete signal is outputted without changing the attenuation characteristics of the switched capacitor. On account of this, there is no need to provide an anti-aliasing filter in front of the switched capacitor.

The following describes how this filter works, with reference to a third-order low-pass filter including switched capacitors with an anti-aliasing function, as shown in FIG. 4.

The filter includes integration circuits of three stages serially connected to one another. The first stage is an incomplete integration circuit including an amplifier A1 (101 in the figure), an input resistor R1 (131), a feedback resistor R2 (132), a feedback capacitor C1 (133), and a feedback capacitor C1 (141). The second stage is an integration circuit including an amplifier A2 (102), an input resistor R3 (133), and feedback capacitor C2 (142). The third stage is an incomplete integration circuit including an input resistor A3 (103), an input switched capacitor SC3 (113), a feedback switched capacitor CS4 (114), and a feedback capacitor C3 (143). The input of the amplifier in the first stage is connected to the output of the amplifier in the second stage via the switched capacitor SC1 (111), and the input of the amplifier in the second stage is connected to the output of the amplifier in the third stage via the switched capacitor SC2 (112).

Here, a circuit having ideally an infinite gain at zero frequency is defined as an “integration circuit.” A circuit having a finite gain at zero frequency is called an “incomplete integration circuit.”

It should also be noted that the filter is first designed as a switched capacitor filter having switched capacitors, and the resistors R1 (131) through R3 (133) later replace the switched capacitors. Because of the replacement, the characteristics of the filter slightly change from its original characteristics. On the account of this, it is necessary to adjust the resistance of the input resistor, the resistance of the feedback resistor, the capacitance of the feedback capacitor and the capacitance of the capacitor in the switched capacitors. With the structure, the filter can process a continuous-time analog signal in the first and second stages. The circuits of the first and second stages work as a low-pass filter for a continuous-time signal, and anti-aliasing function is realized. Because of this, aliasing noise is removed from the frequency outputted from the second stage circuit.

The third stage circuit is designed to process only a discrete-time signal. Therefore, it needs to sample a signal outputted from the second stage circuit. Accordingly, a switch in the switched capacitor SC3 (113) is operated so that the capacitor terminals of the switched capacitor SC3 (113) are not connected to the output of the amplifier A2 (102) and the input of the amplifier A3 (133), simultaneously. The discrete-time signal also passes through the first circuit and the second circuit via the switched capacitors SC1 (111) and SC2 (112) which are connected to the output of the third stage circuit. As a result, the filter outputs a discrete-time signal having a their-order low-pass characteristic. In other words, the filter includes a second-order anti-aliasing filter in a third-order switched capacitor low-pass filter.

The charge stored in the capacitor at every sampling needs to be preserved without leak until the next sampling is carried out. This is necessary to effectively operate the switched capacitor circuit, which is an essential circuit of the switched capacitor filter. Therefore, a metal-oxide-semiconductor field-effect-transistor (MOS FET, referred to as MOS transistor hereinafter) having a very high impedance on the order of 1TΩ (10¹² Ω) is used for the input section of an amplifier to which the switched capacitor is connected. Evidently, the MOS transistor has been used for the input section of an amplifier in the switched capacitor filter having an anti-aliasing function proposed by the inventors of the present invention.

FIG. 5 is an example of an amplifier in which MOS transistors are used.

The amplifier shown in FIG. 5 has a structure known as the “folded-cascode” structure. The input stage of the amplifier constitutes a differential amplifier that includes (i) N-channel MOS transistors M1 (501 in the figure) and M2 (502), provided as a signal input section, (ii) P-channel MOS transistors M3 (203) and M4 (204), provided as loads, and (iii) a constant current supply I (211) which supplies a bias current to the MOS transistors. In the second stage, a P-channel transistor M5 (205) is coupled to the transistor M1 (501) and a P-channel transistor M6 (206) is coupled to the transistor M2 (502), thus making up a folded-cascode circuit. N-channel transistors M7 (207) and M8 (208) are connected as loads to the transistor M5 (205) and the transistor M6 (206), respectively. Instead of the transistors M3 (203), M4 (204), M7 (207), and M8 (208), resistors may be used.

Furthermore, optimum bias voltages bias1, bias2, and bias3 are supplied to the respective gates of the transistors M3 (203) through M8 (208).

A signal voltage supplied between the gate of the transistor M1 (501) and the gate of M2 (502) is converted to a source-drain current of the transistors M1 (501) and M2 (502). The source-drain current of the transistors M1 (501) and M2 (502) varies the current flowing through the transistor M5 (205) and the transistor M6 (206). The current is then converted into a voltage by the output resistance of the transistors M7 (207) and M8 (208). As a result, a signal voltage is produced. On this occasion, the differential output voltage produced between the source of the transistor M7 (207) and the source of the transistor M8 (208) is amplified. Because it is difficult for a current to flow into the gates of the transistor M1 (501) and the transistor M2 (502) of the input section, very high input impedance can be obtained.

Incidentally, in the MOS transistor, large noise (1/f noise or flicker noise) having frequency characteristics of a power which is inversely proportional to frequency is produced. In amplifying circuits and filters, the noise generated in the input section determines the total noise of the circuit. On the account of this, when the switched capacitor filter needs to satisfy a large SN ratio, the 1/f noise can be a problem. The filter described in the foregoing publication (shown in FIG. 6(a)) was fabricated for a baseband section of a super-heterodyne receiver in W-CDMA mobile phones which belong to a group of third generation mobile phones. Thus, the input signal of the filter is limited to a certain band by the other filters in an intermediate frequency (IF) section, and the amplifier. Furthermore, the input signal of the filter has a high signal level, but a low interference wave level. Therefore, it is permitted that the noise level of the filter is not so small.

However, in digital wireless receiver such as a digital terrestrial television and multi-channel wireless communication receiver, a switched capacitor having anti-aliasing function is used for an IF section or a baseband section of a low-IF receiver (in which intermediate frequency is very low), and a zero-IF receiver or a direct-conversion receiver (in both of which no intermediate frequency is used) as shown in FIG. 6(b), so that a desired channel can be selected. The filter used in the baseband section is a band-pass filter, but a low-pass filter may be used instead of a band-pass filter. With this arrangement, an RF section is not band-limited almost at all. Even if it is band-limited, a desired channel can be received, and an excessively wider band frequency component is supplied to the filter. Also, in this case, an interference wave, which is a frequency component excluding a signal of the desired channel, can be much higher than the signal level. In light of this, the input level of the filter requires to be adjusted to the interference level so that the filter does not saturate to disable the filtering function. In this case, the input level of signal is notably small, and the difference from the level of the 1/f noise generated by the filter itself becomes smaller. As a result of this, the 1/f noise cannot be ignored.

In order to remove the 1/f noise, a chopper may be used. This method is described in Japanese Publication for Unexamined Patent Application No.7-202637 (Tokukai No.7-202637, published on Aug. 4, 1995). A low-pass filter in accordance with this method is described below with reference to FIG. 7.

In FIG. 7, the upper diagram is a block diagram of a low-pass filter. The lower graphs illustrate input-output frequency characteristics of respective blocks in the upper diagram. The horizontal axis of the graph represents frequency, and the vertical axis of the graph represents amplitude or power. The input of a switched capacitor hi-pass filter 401 whose sampling frequency is 2Fs is multiplied by Frequency Fs using a multiplier 402. The output of the switched capacitor hi-pass filter 401 is multipled by a rectangular wave signal Ssw whose amplitude is ±1, using a multiplier 403. On the account of this, the input signal and the output signal of the filter are chopped. This means that the input and output of the switched capacitor high-pass filter 401 are modulated by the rectangular wave signal. Because of this, a signal component Sin in the input signal of the multiplier 402 is is shifted to the vicinity of Fs in the output signal of the capacitor 402. The shifted Sin is filtered in the filter 401, and then a signal component Sf is outputted.

On the other hand, 1/f noise N produced in the filter 401 stays in a low frequency range. In the output of the multiplier 403, the filtered signal component Sf in the vicinity of frequency Fs has been shifted to a low frequency range. Consequently, the 1/f noise N is shifted to the vicinity of frequency Fs, and the 1/f noise N does not appear in a low frequency range. As a result of this, an SN ratio in a low frequency range is improved.

However, in the method using a chopper, the filter input signal Sin needs to be band-limited beforehand as shown in FIG. 7. Therefore, in order to apply this method to the switched capacitor having an anti-aliasing function, another low-pass filter for band-limiting, i.e., an anti-aliasing filter requires to be additionally provided in advance. In this case, the embedded anti-aliasing function has no use.

### SUMMARY OF THE INVENTION

An object of the present invention is to provide a switched capacitor filter having an anti-aliasing function for reducing 1/f noise.

To achieve the object, a switched capacitor filter having an anti-aliasing function of the present invention includes (i) integration circuits of multiple stages, each having an amplifier and a switched capacitor, (ii) the integration circuit of at least a first stage having a resistor, and (iii) an amplifier in at least one of the integration circuits including a bipolar transistor.

The 1/f noise generated in a bipolar transistor is much smaller than that generated in a MOS transistor. Accordingly, 1/f noise of the entire filter can be reduced.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a circuit diagram of a switched capacitor filter having an anti-aliasing function in one embodiment of the present invention.

FIG. 2 is a circuit diagram illustrating an input-stage circuit in a first-stage amplifier of the circuit shown in FIG. 1.

FIG. 3 represents frequency-input referred noise characteristics of the switched capacitor filter having an anti-aliasing function, comparing frequency characteristics when the present invention was applied and when the present invention was not applied.

FIG. 4 is a circuit diagram showing an example of a conventional switched capacitor filter having an anti-aliasing function.

FIG. 5 is a circuit diagram illustrating an example of an input-stage circuit of a first-stage amplifier of the circuit shown in FIG. 4.

FIG. 6(a) is a block diagram of a super-heterodyne wireless receiver.

FIG. 6(b) is a block diagram of a low-IF or a zero-IF wireless receiver.

FIG. 7 illustrates a conventional method for reducing 1/f noise by using a chopper.

### DESCRIPTION OF THE EMBODIMENTS

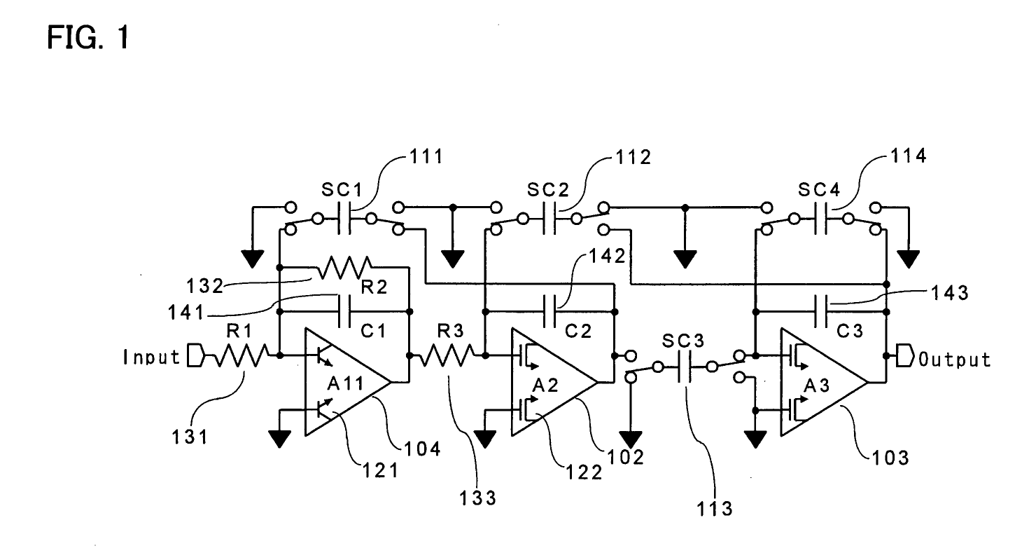

A preferred embodiment of the present invention is explained below with reference to FIG. 1 through FIG. 3.

FIG. 1 is a circuitry of a switched capacitor third-order low-pass filter incorporating anti-aliasing function according to the present invention.

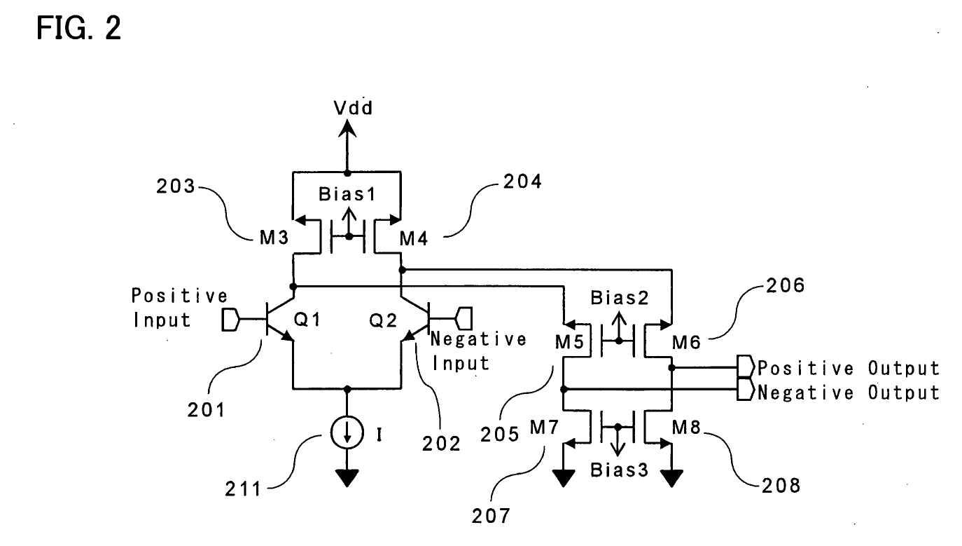

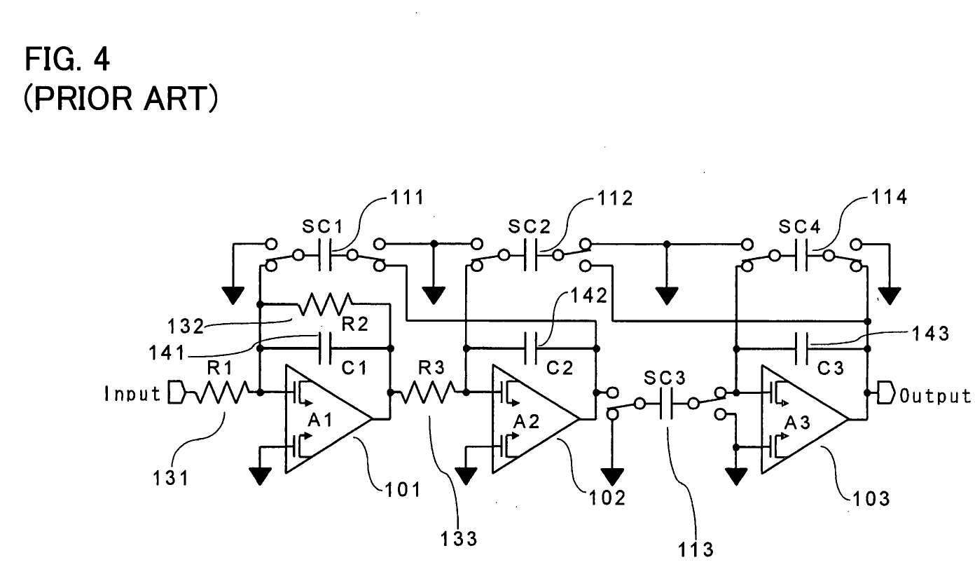

Because a basic structure of this low-pass filter is the same as the conventional switched capacitor filter shown in FIG. 4, details thereof are omitted. However, the low-pass filter of the present embodiment differs from the conventional switched capacitor filter in that the input stage of an amplifier All (indicated by reference numeral 104 in the figure) on the first stage includes bipolar transistors. An example of this amplifier is shown in FIG. 2.

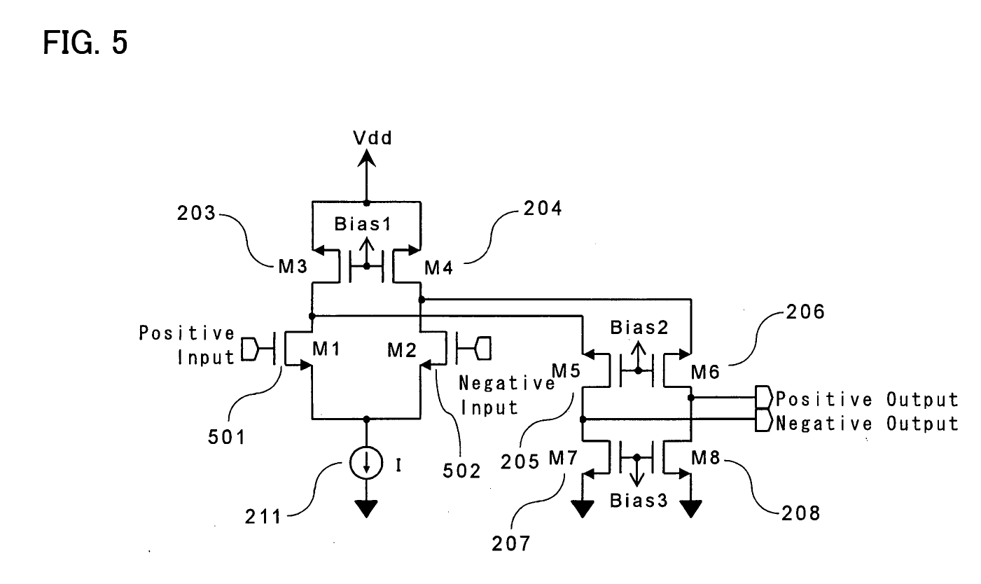

Specifically, the amplifier shown in FIG. 2 uses NPN bipolar transistors Q1 (201) and Q2(202) for the input MOS transistors M1 (501) and M2 (502) provided on the input stage of the differential folded cascode amplifier used in the conventional switched capacitor filter described in FIG. 5. The input impedance of bipolar transistors in a grounded-emitter amplifier is considerably smaller than the input impedance of MOS transistors in a grounded-source amplifier. On the account of this, the input impedance across the positive input and negative input of the amplifier operating as a differential amplifier is considerably smaller than that in the structure shown in FIG. 5.

It should be noted, however, that the input impedance must be sufficiently greater than the resistance of a resistor R1 (131) or R2 (132) connected to the amplifier A11 (104) of the first stage. In this way, the effect of the input impedance on filter characteristics can be ignored. The reason for this is as follows. In the amplifier A11 (104) of the first stage, the charge stored in a switched capacitor SC1 (111) every time sampling is carried out leaks through the resisters R1 (131) and R2 (132). Accordingly, a charge which leaks into the transistors can be ignored when the input impedance of the amplifier A11 (104) is sufficiently greater than the resistance of the resistor R1 (131) or R2 (132). Details about this will be described later.

One characteristic of the bipolar transistor is that its 1/f noise is much smaller than that of the MOS transistor. Therefore, the amplifier A11 (104) having bipolar transistors in the input section generates 1/f N noise that is much smaller than 1/f noise generated in the conventional amplifier having MOS transistors in the input section. Particularly, in a filter having a gain in the first stage of an integration circuit, the noise generated in the input stage of the amplifier 1 is the dominating noise in the filter. Therefore, reducing the 1/f noise by using the bipolar transistors is highly effective in reducing noise.

Accordingly, more 1/f noise can be reduced when the bipolar transistors are used not only for the bipolar transistors Q1 (201) and Q2 (202) in the input section of the input stage but also for the MOS transistors M3 (203) and M4 (204) that constitute a load. The 1/f noise can be reduced even more effectively when the bipolar transistors are used for (i) either a pair of MOS transistor M5 (205) and M6 (206) or a pair of MOS transistor M7 (207) and M8 (208), or (ii) the both pairs on the next stage. However, the effects of reducing 1/f noise by replacing the MOS transistors with the bipolar transistors becomes weaker as the distance the input section of input stage is increased.

In some filters, in order to present signal saturation in each section of the respective stages, a gain of integration circuits may be greater in stages other than the first stage, or the integration circuit of the first stage may attenuate even a signal band. In this case, the effect of reducing the total 1/f noise of the filter may not be obtained effectively when the bipolar transistor is used only for the input stage of the amplifier A11 (104) in the integration circuit of the first stage. Further, using the bipolar transistor only for the input stage of the first-stage amplifier may not be enough to reduce the 1/f noise to a sufficient level in the filter.

In order to avoid such problems, the bipolar transistors may be used not only for the first stage of the amplifier A11 (104) but also for the input stage of all the amplifiers that adversely affect the total 1/f noise of the filter. Here, such amplifiers are selected from the integration circuits in which resistors are used instead of the switched capacitors. In the filter shown in FIG. 1, the amplifiers A11 (104) and A12 (102) are among the amplifiers in the integration circuits in which the switched capacitors are replaced with resistors. Therefore, the bipolar transistors of FIG. 2 are used for the input stage of either one of or both of the amplifiers A11 (104) and A12 (102).

Incidentally, when the switched capacitor filter of the present invention is used as the band-pass filter or low-pass filter in the IF section of the low-IF system or the base-band section of the zero-IF system, a gain of each stage is determined in such a manner as to prevent a signal component from being distorted by a saturated interference wave component in each section of the respective stages, which may occur when an interference wave component (frequency component outside the pass band of the filter) enters the filter at its expected maximum level with the signal component. In this case, the bipolar transistors may also be used for the input stages of all the amplifiers that adversely affect the 1/f noise of the filter.

As described above, the switched capacitor filter having an anti-aliasing function has an integration circuit in which the switched capacitors are replaced with resistors. The resistors so replaced leak the charge of the other switched capacitors in the integration circuit. Therefore, the resistance and capacitance of the resistors, capacitors, and the capacitors in the switched capacitor are all adjusted so that the leaked charge does not change the characteristics of the filter.

The input impedance of the amplifier in the integration circuit in which the switched capacitors are replaced with the resistors does not affect the characteristic of the filter even when the input impedance is not as large as the input impedance of the MOS transistor, provided that the input impedance is sufficiently greater than the resistance of the resistor. For example, with an input impedance of several hundred kΩ with respect to a resistance of several kΩ, the effect of input impedance is almost negligible. A several hundred kΩ input impedance can be realized even with an amplifier whose input stage includes bipolar transistors. Therefore, the 1/f noise of the filter can be reduced by using bipolar transistors for the input stage of the amplifier in the integration circuit with the replaced resistors.

Therefore, only in the switched capacitor filter having an anti-aliasing function, bipolar transistors can be used for the input stage of an amplifier of the integration circuit in which resistors are used. On the account of this, 1/f noise can be reduced.

It should be noted that when the resistance has several hundred kΩ that compares to the input impedance of the amplifier, the resistance and capacitance of the filter may be adjusted taking into account the input impedance. However, caution is needed that the input impedance of the amplifier varies greatly depending on product variations or temperature characteristics of the bipolar transistor.

Recently, it has become common to fabricate the bipolar transistors and MOS transistors on a single IC substrate through a BiCMOS process. The BiCMOS process can also be used to fabricate the switched capacitor filter of the present embodiment in which the bipolar transistors are used for the input stage of one or more amplifiers. On the account of this, the filter can be realized in the form of a several square millimeter LSI.

Furthermore, a low-noise analog-front-end LSI for digital demodulation can be realized when the filter is embedded in a single chip together with a radio frequency amplifier, a frequency-conversion circuit, and an A/D converter. On the account of this, the number of parts can be reduced, and the area occupied by the parts can be made smaller. Accordingly, this technique can be applied for reducing size of an electric device such as a mobile phone.

Referring to the circuit diagram of FIG. 1, the foregoing mainly described the third-order switched capacitor filter having second-order anti-aliasing function. However, the present invention is not limited to the switched capacitor filter having anti-aliasing function of particular orders, and the present invention is applicable to any type of switched capacitor filter having anti-aliasing function.

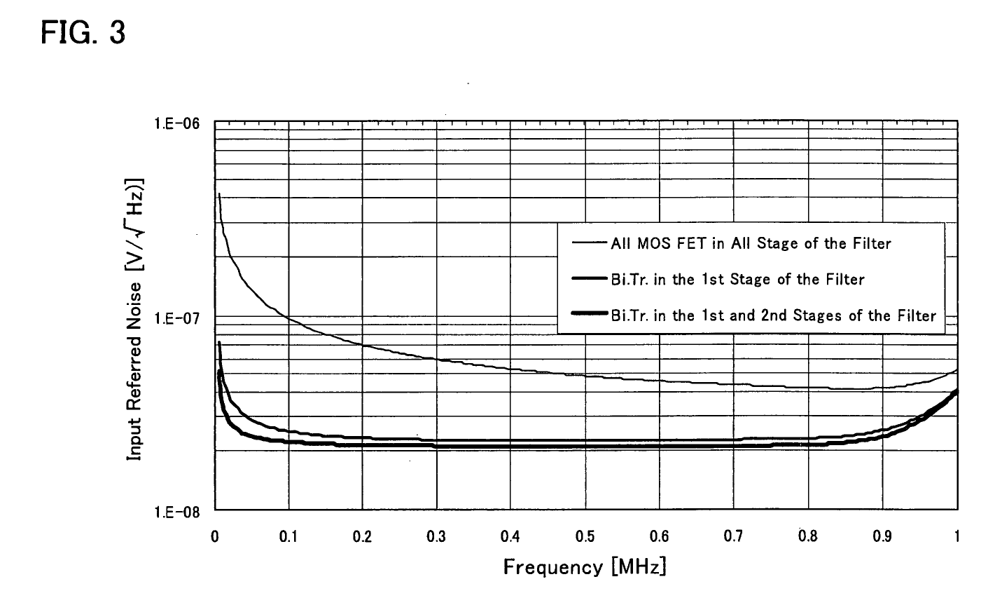

Here is an example of how the switched capacitor having anti-aliasing function reduces 1/f noise. FIG. 3 represents a result of simulation for the frequency characteristics of input referred noise of a switched capacitor filter. Here, the switched capacitor filter incorporates second-order anti-aliasing function in a seventh-order elliptic low-pass filter having a cut-off frequency of 800 kHz and a 20 dB gain in its pass band. The filter was fabricated in accordance with a 0.5 μm rule BiCMOS process.

The BiCMOS process enables NPN bipolar transistors, N-channel MOS transistors, and P-channel MOS transistors to be fabricated on a silicon substrate. The filter uses the folded-cascode amplifiers as shown in FIG. 2 and FIG. 5 for its amplifiers in the first-stage and second-stage integration circuits. FIG. 3 illustrates input referred noise (1) when MOS transistors are used in all stages of the filter (corresponding to FIG. 5), (2) when the N-channel MOS transistors are replaced with NPN bipolar transistors only in the amplifier of the first-stage integration circuit (when the MOS transistors M1, M2, M7, and M8 in FIG. 5 are replaced with bipolar transistors), and (3) when the N-channel MOS transistors are replaced with NPN bipolar transistors in the amplifiers of the first-stage and second-stage integration circuits.

As shown in FIG. 3, the configuration (1) to which the present invention is not applied produces large 1/f noise, causing a voltage to decrease as the frequency increases. On the other hand, in the configurations (2) and (3) to which the present invention is applied, 1/f noise decreases dramatically. However, difference between amount of 1/f noise in the configuration (2) and amount of 1/f noise in the configuration (3) is not so huge as difference between amount of 1/f noise in the configuration (1) and amount of 1/f noise in the configuration (2). That is, an effect of applying the present invention to the amplifier of the first stage of the integration circuit is much greater than an effect of applying the present invention to the amplifier of the second stage of the integration circuit. In addition, the filter has 14 dB gain in the first stage, and 6 dB gain in the second stage.

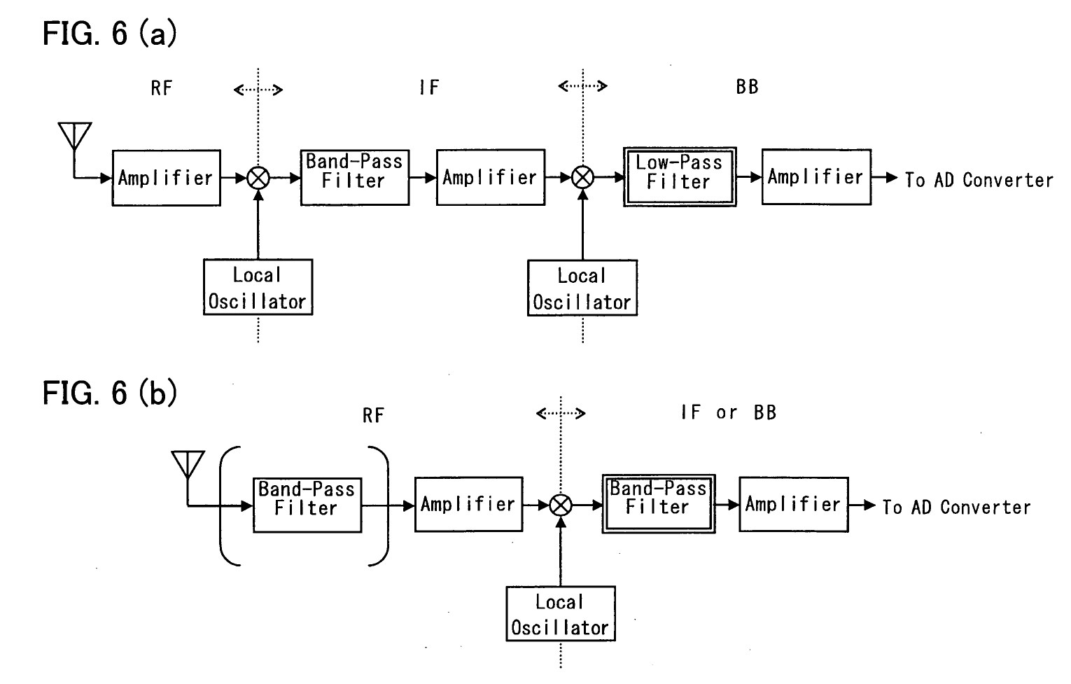

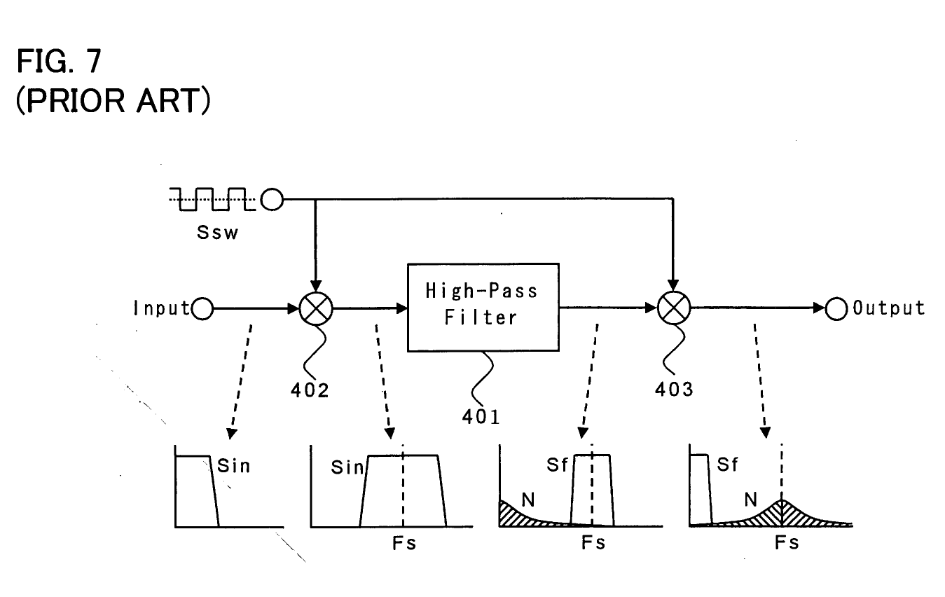

The 1/f noise can be reduced more effectively when the present invention is applied to the band-pass filter (or low-pass filter) of the IF section or baseband section of the low-IF receiver and zero-IF receiver shown FIG. 6(b). Thus, with the present invention, a sufficiently high S/N ratio can be obtained even when the signal level is held at low level to prevent the filter from being saturated by a high amplitude level of an interference wave in the input signal of the filter. This is evident from the respective characteristics of the foregoing configurations (1), (2), and (3) as shown in FIG. 3.

As described above, a switched capacitor filter having an anti-aliasing function includes (i) integration circuits of multiple stages, each having an amplifier and a switched capacitor, (ii) an integration circuit of at least a first stage having a resistor, and (iii) an amplifier in an integration circuit at least the first stage including a bipolar transistor. The 1/f noise generated in a bipolar transistor is much smaller than that generated in a MOS transistor. Accordingly, the 1/f noise of the entire filter can be reduced.

The switched capacitor filter having an anti-aliasing function includes integration circuits of multiple stages, each of which is provided with an amplifier and a switched capacitor, and in which a resistor is used for an integration circuit of at least a first stage. In the switched capacitor filter, the input stage of one or more amplifiers using a resistor is a switched capacitor filter having a bipolar transistor. Therefore, the 1/f noise generated in the input stage of the amplifiers is reduced. Most noise in the amplifiers is produced from the input stage of the amplifiers. Accordingly, a large amount of 1/f noise in the switched capacitor filter can be reduced.

Each integration circuit has a distributed gain to maintain a filtering function in each of the multiple stages, and the input stage of an amplifier which shows strong 1/f noise reduction effect includes bipolar transistors. On the account of this, 1/f noise can be effectively reduced without disabling the filtering function as caused when the filter is saturated by a considerably lower signal level than an interference wave (a frequency component excluding a signal of desired channel).

The amplifier including bipolar transistors in the input stage of the filter has input impedance that is sufficiently greater than the resistance of the resistor connected to the input of the amplifier. Accordingly, the charge of switched capacitor leaking into the amplifier can be reduced considerably from the charge initially leaking into the resistor. On the account of this, the characteristics of the filter are hardly different from the characteristics of a filter in which MOS transistors are used for the input stage.

The switched capacitor filter in which the bipolar transistors are used is fabricated on a single substrate. On the account of this, a low noise switched capacitor filter having an anti-aliasing function of the present invention can be provided in a single-chip LSI. Alternatively, the switched capacitor filter may be embedded together with other circuits in a single composite chip LSI. Accordingly, the number of parts can be reduced, and the area occupied by the parts can be made smaller. This is effective in reducing the size of products which use the chip prepared this way.

The switched capacitor in which the bipolar transistors are used is used for (i) intermediate frequency band section of a digital wireless receiver or a digital wireless communication receiver which uses a low intermediate frequency, and (ii) an analog base band section of a digital wireless receiver or a digital wireless communication receiver which uses no intermediate frequency. On the account of this, the SN ratio of a desired signal to its noise can be increased, because the filter itself generates only small 1/f noise even when the desired signal is inputted with a small amplitude level while an interference wave with a large amplitude level is not attenuated enough. Accordingly, the reception sensitivity of digital wireless broadcasting is not spoiled.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

1. A switched capacitor filter having an anti-aliasing function, comprising:
integration circuits of multiple stages, each having an amplifier and a switched capacitor, and
wherein
an integration circuit of at least a first stage of the integration circuits of multiple has a resistor, and
the amplifier in at least one of the integration circuits includes a bipolar transistor.

2. A switched capacitor filter having an anti-aliasing function, comprising:
integration circuits of multiple stages, each having an amplifier and a switched capacitor, and
wherein
the integration circuit of at least a first stage of the integration circuits of multiple has a resistor, and
the bipolar transistor is provided in an input stage of the amplifier in at least one of the integration circuits having the resistor.

3. A switched capacitor filter having an anti-aliasing function, comprising:
integration circuits of multiple-stages, each having an amplifier and a switched capacitor, and
wherein
an integration circuit of at least a first stage of the integration circuits of multiple has a resister,
the integration circuits each has a distributed gain so as to maintain a filtering function in each of the multiple-stages of integration circuits, and
an input stage of an amplifier which shows a strong 1/f noise reduction effect includes a bipolar transistor.

4. The switched capacitor as set forth in claim 2, wherein:
the amplifier whose input stage includes the bipolar transistor has an input impedance that is greater than a resistance of the resistor which is connected to the input stage of the amplifier.

5. The switched capacitor as set forth in claim 3, wherein:
the amplifier whose input stage include the bipolar transistor has an input impedance that is greater than a resistance of the resistor which is connected to the input stage of the amplifier.

6. The switched capacitor filter as set forth in claim 1, wherein:
the switched capacitor filter is provided on a single substrate.

7. The switched capacitor filter as set forth in claim 2, wherein:
the switched capacitor filter is provided on a single substrate.

8. The switched capacitor filter as set forth in claim 3, wherein:
the switched capacitor filter is provided on a single substrate.

9. A digital wireless receiver, wherein:
the switched capacitor filter of claim 1 is used for (i) intermediate/frequency band section of a digital wireless receiver which uses a low to intermediate frequency, or (ii) an analog baseband section of a digital wireless communication receiver which uses no intermediate frequency.

10. A digital wireless receiver, wherein:
the switched capacitor filter of claim 2 is used for (i) intermediate frequency band section of a digital wireless receiver which uses a low to intermediate frequency, or (ii) an analog baseband section of a digital wireless communication receiver which uses no intermediate frequency.

11. A digital wireless receiver, wherein:
the switched capacitor filter of claim 3 is used for (i) intermediate frequency band section of a digital wireless receiver which uses a low to intermediate frequency, or (ii) an analog baseband section of a digital wireless communication receiver which uses no intermediate frequency.
